(19) United States
(12) Patent Application Publication
(10) Pub. No.: US 2025/0126946 A1
(43) Pub. Date: Apr. 17, 2025

(54) TARGET CARRIER, SEMICONDUCTOR DEVICE AND METHOD FOR TRANSFERRING A SEMICONDUCTOR COMPONENT AND HOLDING STRUCTURE

(71) Applicant: ams-OSRAM International GmbH, Regensburg (DE)

(72) Inventors: Tobias Berthold, Wenzenbach (DE); Markus Boss, Regensburg (DE); Thomas Schwarz, Regensburg (DE); Sebastian Wittmann, Regenstauf (DE)

(21) Appl. No.: 18/834,566

(22) PCT Filed: Feb. 1, 2023
(86) PCT No.: PCT/EP2023/052447

§ 371 Date: Jul. 30, 2024

(30) Foreign Application Priority Data
Feb. 1, 2022 (DE) 10 2022 102 367.2

(51) Int. Cl. H10H 29/03; H01L 21/683

(52) U.S. Cl. CPC H10H 29/03; H01L 21/6835

(57) ABSTRACT

In an embodiment a target carrier for transferring semiconductor components includes a target substrate with at least two contact areas and a shrinkable collecting layer arranged around each of the at least two contact areas and projecting beyond the at least two contact areas, wherein a lateral distance between two opposite edges of the shrinkable collecting layer around each of the at least two contact areas is smaller than a lateral dimension of the at least one contact pad of the semiconductor components, wherein the shrinkable collecting layer around the at least two contact areas is designed such that its structuring is configured to penetrate into the shrinkable collecting layer with a substantially central alignment of the at least one contact pad relative to one of the at least two contact areas.

### CROSS-REFERENCE TO RELATED APPLICATIONS

This patent application is a national phase filing under section 371 of PCT/EP2023/052447, filed Feb. 1, 2023, which claims the priority of German patent application 10 2022 102 367.2, filed Feb. 1, 2022, each of which is incorporated herein by reference in its entirety.

### TECHNICAL FIELD

The present invention relates to a semiconductor device and a method for transferring a semiconductor components.

### BACKGROUND

Semiconductor components, including so-called μLEDs, must be transferred from a source carrier or output substrate to a target carrier. The term “target carrier” is understood to mean another temporary carrier, but also a circuit board, a PCB, a backplane or similar. When components are transferred using a so-called laser-induced forward transfer (LIFT-Off process), components are detached from the source carrier by a laser pulse and then transferred to the target carrier. In a second step, the component is then attached to the target carrier. It is expedient to use a process that can transfer a large number of components in a very short time. Such a transfer is particularly difficult with small components, the above-mentioned μLEDs, as their lateral dimensions are only in the range of a few μm.

It is known to realize a transfer to a target surface by means of a collecting layer applied over a large area. There are various approaches to materials that are suitable for the transfer. However, such a transfer often requires one or more intermediate steps until the transfer to a target carrier, to which the components are finally attached using a solder material.

### SUMMARY

Embodiments provide a transfer process that reduces the effort required for the transfer. Further embodiments enable a transfer process not only for very small components, but also for larger components or more complex designs with several connection contacts.

The inventors propose using a structured collecting layer directly on a target carrier so that when the components are transferred, they are caught and held on the target carrier by means of the shrinkable collecting layer. This enables reliable transfer to a non-conductive adhesive layer with simultaneous implementation of a reliable electrical connection. By using a suitable material that changes its volume by means of a shrinking process, it is also possible to achieve an improvement in the electrical contact through the transfer process. In this way, components can be placed directly onto a finished backplane, a carrier, an interconnect layer or another component without the need for an additional intermediate step, in particular an additional transfer step.

A structuring of such a collecting layer can be realized by means of lithography processes for very small components or a locally limited application of the material of the shrinkable collecting layer for large components. In particular, it is possible to use known lithographic processes, for example for producing a structured photoresist layer, also for structuring such a collecting layer. Possible materials that can be used include materials with a very high coefficient of thermal expansion or materials that harden when heated or undergo a change in volume due to another parameter change. This takes place in such a way that the shrinkable collecting layer shrinks, i.e. its volume is reduced.

This exerts a tensile force on the component, resulting in improved mechanical and electrical contacting even without a soldering process. A subsequent contacting process results in improved contacting of the component, as this is already under a certain tensile force. In addition, adhesions or displacements can be easily compensated for by suitable measures, resulting in improved positioning of the component on the carrier.

In one aspect of the proposed principle, a target carrier is therefore provided which is designed for transferring semiconductor components. For this purpose, the semiconductor components comprise at least one contact pad and a structuring. The target carrier has at least two contact areas which are surrounded at a distance by a catch layer. The shrinkable collecting layer is thus arranged around each of the at least two contact areas and also projects beyond them. The distance around each of the at least two contact areas is smaller than a lateral dimension of the at least one contact pad of the semiconductor component to be transferred. This means that during a transfer, a contact pad of the semiconductor component protrudes beyond the contact area and thus comes to rest at least partially on the shrinkable collecting layer. Since the shrinkable collecting layer also protrudes slightly beyond the two contact areas, there is a slight gap between the underside of the contact pad and the upper side of the corresponding contact area. In addition, structuring of the semiconductor component is provided. The shrinkable collecting layer around the at least two contact areas is designed in such a way that the structuring of the semiconductor component can penetrate into the shrinkable collecting layer when the at least one contact pad is essentially centrally aligned relative to one of the at least two contact areas. In addition to the adhesive effect, this also provides mechanical strength through the catch layer. In addition, the improved mechanical retention due to the penetration of the structural element prevents slippage, tilting or other translation of the component during the shrinking process.

In this context, the material of the collecting layer in particular can be designed in such a way that capillary effects or adhesive effects create a particularly intimate bond between the material of the collecting layer and the structuring. Accordingly, a significant improvement is achieved compared to components that do not have this type of structuring. Further embodiments of the semiconductor component that interact appropriately with the collecting layer are described below. They are suitable both here and for the target carriers mentioned below.

The additional air gap is reduced by the shrinkable collecting layer during shrinking, i.e. a further process step, until it disappears completely and the contact pad comes into direct contact with the contact area. In addition, the shrinkable collecting layer can exert a tensile force on the semiconductor component during the shrinking process and “attract” it with the contact pad to the respective contact area.

In one aspect of the proposed principle, a top surface recessed from material of the shrinkable collecting layer around each of the at least two contact areas is smaller than a surface of the at least one contact pad. This ensures that when the semiconductor component is correctly aligned and positioned after transfer of the component to the target carrier, the contact pad comes to rest at least partially on the surface of the shrinkable collecting layer.

The shrinkable collecting layer undergoes a change in volume as a result of the shrinking process, whereby it is possible in some aspects that the shrinkable collecting layer changes volume not only in terms of its height, but also in its lateral dimensions. In this context, unless otherwise stated, the term “containment layer” always refers to a shrinkable collecting layer. A characteristic property of this containment layer is a desired and sufficiently large volume reduction under the influence of an external effect. Materials which also undergo a volume change during processing, but which are not desired or which are not used as in the proposed principle, namely to generate a tensile force by means of the shrinkable collecting layer through the shrinking process, should therefore be excluded.

In order to effectively prevent the shrinkable collecting layer from flowing onto the contact areas in the event of additional pressure during the shrinking process, it may be provided in some aspects that the material of the shrinkable collecting layer is arranged at a distance around the at least two contact areas. It is possible to select a distance of less than 25% and in particular less than 15% of a lateral dimension of the at least one contact pad or one of the at least two contact areas. This ensures that the material of the shrinkable collecting layer is at a sufficient distance from the two contact areas so that the material of the shrinkable collecting layer does not inadvertently reach the upper side of the contact areas during a subsequent shrinking process, thus preventing possible electrical contacting.

Some aspects deal with the change in volume of the shrinkable collecting layer. For example, this can be designed to shrink when exposed to heat. This means that when the shrinkable collecting layer is heated above a threshold temperature, it begins to shrink until the volume change is complete. Alternatively, the shrinkable collecting layer can also undergo a volume change due to the application of a force that is essentially perpendicular to the contact areas. Here, in some embodiments, it is expedient if the shrinkable collecting layer is arranged at a sufficient distance from the contact areas in order to effectively prevent a flow of material onto the upper side of the contact areas when such a force is applied. In a further aspect, the shrinkable collecting layer is provided with an additional liquid component which evaporates during the process, causing the shrinkable collecting layer to change its volume. In this aspect, the evaporation of the liquid component leads to a shrinkage of the volume of the shrinkable collecting layer. In a further alternative embodiment, a shrinking process takes place through a chemical process, in particular through cross-linking. This changes the structure and the material of the shrinkable collecting layer in such a way that it is reduced in volume during the chemical process.

In this context, it is expedient in some aspects to apply a thin layer of a solder material to the at least two contact areas. This can be designed such that it extends at least up to a surface of the shrinkable collecting layer. In some aspects, the solder layer is thinner, but should not extend beyond the surface of the shrinkable collecting layer to ensure capture of the component on the shrinkable collecting layer during a transfer process.

The solder material can comprise a low-melting solder, in particular a metal solder compound such as AuSn or AuIn. In some aspects, the melting point of this solder compound is higher than the temperature required for the shrinking process of the shrinkable collecting layer. Some further aspects deal with lateral dimensions in more complex semiconductor components, in particular comprising two or more contact pads. In these aspects, a distance between centers of the at least two contact areas on the target carrier is selected to match a distance between centers of two or more contact pads of the semiconductor components. Correct centered alignment thus ensures that the larger area of the contact pads of the semiconductor components is centered over the area of the contact areas on the target carrier.

In some aspects, it may be advantageous to additionally provide an alignment element which is suitable for alignment and better locking or positioning. In some embodiments, this alignment element may be formed on the contact pad or on the contact areas. In some other aspects, an alignment element is provided on at least one of the contact pads, which corresponds to a corresponding alignment element on one of the contact areas of the target carrier. During an alignment and a subsequent shrinking process, these two alignment elements can interlock and effect an exact positioning of the semiconductor component in the contact areas.

In another aspect, the target carrier comprises an alignment element which protrudes above the shrinkable collecting layer and corresponds to an alignment element of the semiconductor component in such a way that the alignment element of the target carrier is aligned with the alignment element of the semiconductor component. Such alignment elements, also known as alignment structures, can be provided in different shapes, heights and sizes. When structuring the target carrier with the shrinkable interception layer, the alignment elements can also be surrounded by material from the shrinkable interception layer at a slight distance so that the alignment elements are not damaged, deformed or otherwise displaced during a subsequent shrinking process. The alignment elements can be used in particular to prevent tilting, but also incorrect positioning of the semiconductor component on the surface of the target carrier.

In some aspects, the shrinkable collecting layer comprises a photoresist material comprising an epoxy. In this context, the material is used to pattern the shrinkable collecting layer and the photoresist material has a tacky surface so that the semiconductor component adheres well during the transfer process. In contrast, the epoxy component within the shrinkable collecting layer can be used for the volume change. In another aspect, a material comprising a silicone having a high coefficient of thermal expansion is provided. In some aspects, a material composition combining the various necessary properties is provided. For example, not only the coefficient of thermal expansion plays a role, but also the chemical shrinkage during curing. Silicones have a high coefficient of expansion, which is typically roughly between 100 and 400 ppm/K. At the same time, the chemical shrinkage is around 12% to 20%, although in some versions it is somewhat higher. In general, however, it is 30% or less, in particular less than 25%.

Some other aspects deal with the difference in height between the shrinkable collecting layer and the contact area. On the one hand, this difference in height must be sufficiently compensated for by the subsequent shrinking process so that the component with its contact pads is in direct contact with the contact areas. On the other hand, this difference should not be too small so as not to cause the shrinkable catch layer to detach from the contact areas of the semiconductor component during the shrinking process. In one aspect, therefore, a difference between a height of the at least two contact areas and a surface of the shrinkable collecting layer is in the range of less than 25% of a thickness of the shrinkable collecting layer. The thickness of the shrinkable interception layer can be between 300 nm and 2.5 μm and in particular in the range of 800 nm to 1.5 μm.

Another aspect relates to a semiconductor device with a target carrier according to the proposed principle disclosed above and with the aspects already mentioned. The semiconductor device further comprises a semiconductor component having a semiconductor body and at least one contact pad. The contact pad is mechanically and electrically attached to one of the at least two contact areas, in particular, for example, via a solder. The contact pad protrudes beyond the surface of the contact area. A protruding part is at least partially connected to the shrinkable collecting layer, in particular mechanically.

In one aspect, the material of the shrinkable collecting layer extends at least partially along an edge of the contact pad of the shrinkable collecting layer towards the body. In some aspects, this material at the edge of the contact pad is formed by a capillary effect.

In a further aspect, the contact pad or also the contact area comprises a structuring. In the case of a structuring on the contact pad, this can be designed to penetrate into a surface of the shrinkable collecting layer adjacent to the at least one of the at least two contact areas. For this purpose, the structuring can be arranged in the edge area of the contact pad, for example.

Alternatively, it is also possible for the structuring to be positioned opposite one of the at least two contact areas. In this context, it is conceivable that a structuring is provided on a contact pad and a structuring is provided on one of the at least two contact areas so that they interlock during a transfer process and a subsequent shrinking process.

In a further aspect, the structuring can comprise at least one locking and alignment element projecting beyond the contact pad. This can engage in the shrinkable catch layer and serves, for example, to prevent the semiconductor component from slipping or shifting during the transfer process.

Furthermore, capillary effects during the shrinking process cause an additional tensile force on the structuring and its configurations in the direction of the contact areas, which results in improved mechanical contact between the contact pad and the contact area. In some aspects, the structures mentioned here have a particularly large surface area, so that the material of the collecting layer can engage particularly well.

In a further aspect, the semiconductor body comprises an alignment element that cooperates with the alignment element of the target carrier such that slippage or displacement of the semiconductor body during or after the transfer process is avoided.

In a further aspect, the semiconductor component comprises a solder material provided between the contact pad and the one of the at least two contact areas. The thickness of this solder material may be substantially equal to or less than a distance of the surface of the contact area from the surface of the shrinkable collecting layer. Conveniently, the solder material is applied to the contact areas during the manufacturing process of the target carrier. Alternatively, however, it is also possible to design the contact pads of the semiconductor body with such a solder material.

In a further aspect, a method for transferring a component from a source carrier to a target carrier is proposed. For this purpose, at least one semiconductor component with at least one contact pad is provided in a first step. The semiconductor component can be an optoelectronic component, a memory device, a logic device, an ASIC or generally an integrated circuit.

A target carrier with at least two contact areas and a shrinkable catch layer is also provided. Here, the shrinkable collecting layer is arranged around each of the at least two contact areas and protrudes beyond the at least two contact areas by a small area. Similarly, a lateral distance between material of the shrinkable collecting layer around each of the at least two contact areas is smaller than a lateral dimension of the at least one contact pad. Various aspects of creating such a target carrier are disclosed below.

The at least one semiconductor component is positioned above the target carrier in such a way that the at least one contact pad lies above the contact area. In particular, it can be centered. Subsequently, the at least one contact pad is placed on an edge of the shrinkable collecting layer over one of the at least two contact areas. A shrinking process is then carried out so that the at least one contact pad is pulled onto the one of the at least two contact areas. The shrinking process can be carried out in various ways. During this process, the semiconductor component is held on the target carrier by the tensile force exerted and the contact pad is in contact with the contact areas. This allows the contact pad to be mechanically and electrically attached to one of the at least two contact areas.

In some aspects, a target carrier is provided. This can be produced independently of the process described above and only subsequently used for the transfer process. Accordingly, a carrier is provided for this purpose and line structures are formed on its surface. The line structures comprise at least two contact areas. A structured shrinkable collecting layer is then formed on the carrier. This can be formed using a stencil process. This is particularly useful for larger structures. For smaller structures, a two-dimensional shrinkable catch layer is applied to the surface of the carrier, for example by spin coating, spin coating, sputtering or other processes. In particular, processes such as those used for photoresist coating can be used for this purpose. In a subsequent step, the applied catch layer is structured and material from the shrinkable catch layer is removed so that the contact areas and an area around the contact areas are exposed.

A photoresist material with an epoxy can be used as the material for such a catch layer. Photoresist material itself is characterized by a certain stickiness, the epoxy produces the necessary shrinkage during a heating process. When using photoresist or a similar material, it is advantageous to use processes that are also used for processing photoresist material.

Another aspect deals with the solder material required for mechanical and electrical attachment. In one aspect, solder material is applied to the at least two contact areas prior to the formation of a structured shrinkable catch layer. This can be a uniform surface but also a small drop or a solder paste. The material of the collecting layer can then be applied until it completely covers the contact areas. In an alternative embodiment, a solder material is squeegeed into openings in the shrinkable catch layer in which the contact areas are exposed. Excess solder material that is still on the surface of the shrinkable collecting layer can then be removed so that a substantially uniform surface is formed.

In a further aspect, at least one alignment element is provided on the target carrier which is aligned with at least one corresponding alignment element of the semiconductor component during positioning of the at least one semiconductor component so that they interlock during the shrinking process. This alignment element can prevent unwanted bouncing or jumping away during placement, especially if a Laser Induced Forward Transfer (LIFT) process is used for the transfer process and the falling component has a higher speed.

In a further aspect, the at least one contact pad of the semiconductor component can also have a structuring at least in its edge region, which engages in the surface of the material of the shrinkable collecting layer during the placement of the semiconductor component. This can be a random roughening, but also a periodic structure, nubs, spikes or other elements that engage with the surface of the material of the collecting layer. Such an element, also referred to as a locking element, may in some aspects also be provided on the semiconductor body. In some aspects, it is intended to provide this structuring with a large surface area so that the structuring and the catch layer are connected to one another over as large an area as possible. In this way, the adhesive force is improved and undesired tilting or displacement during the transfer process and subsequent shrinking process is reduced.

In these cases, the locking element may extend beyond the contact pad(s) so that it engages with the material of the shrinkable collecting layer when the contact pads are placed on the surface of the shrinkable collecting layer. As already indicated above, the shrinkable interception layer can comprise various materials. Among these are a photoresist material comprising an epoxy; and a silicone having a high coefficient of thermal expansion. In some aspects, the material of the capture layer is a combination of different components, which in turn have different functionalities, including a volume change or tackiness.

The shrinking process can be triggered and carried out in various ways. In general, this process can also be supported by exerting additional pressure on the semiconductor body. In one aspect, the collecting layer is heated above a threshold temperature after it has been deposited. The energy supplied causes the collecting layer to shrink. In an alternative aspect, a force substantially perpendicular to the contact areas can also be exerted on the shrinkable collecting layer. This may be appropriate if the containment layer does not have a greater tackiness or coefficient of thermal expansion. In another aspect, the containment layer can be shrunk by vaporizing a solvent or other liquid in the containment layer. In yet another aspect, a volume change occurs by a chemical cross-linking of components in the shrinkable collecting layer.

### BRIEF DESCRIPTION OF THE DRAWINGS

Further aspects and embodiments according to the proposed principle will become apparent with reference to the various embodiments and examples described in detail in connection with the accompanying drawings.

FIGS. 1A and 1B show a schematic representation of a conventional method for transferring components;

FIGS. 2A to 2I show a first embodiment of a method for transferring optoelectronic semiconductor components according to the proposed principle as well as a target carrier and a semiconductor device;

FIGS. 3A to 3F illustrate a second embodiment of a method for transferring optoelectronic semiconductor components as well as a target carrier and a semiconductor device with some aspects according to the proposed principle;

FIGS. 4A to 4E show a third embodiment of a method for transferring optoelectronic semiconductor components as well as a target carrier and a semiconductor device with some aspects according to the proposed principle;

FIGS. 5A to 5H illustrate another embodiment of a method for transferring optoelectronic semiconductor components and a target carrier and a semiconductor device having some aspects according to the proposed principle;

FIGS. 6A to 6D show a further embodiment of a method for transferring optoelectronic semiconductor components as well as a target carrier and a semiconductor device with some aspects according to the proposed principle;

FIGS. 7A to 7F are a further example of a method for transferring optoelectronic semiconductor components and a target carrier and semiconductor device having some aspects according to the proposed principle;

FIGS. 8A to 8H show a further embodiment of a method for transferring optoelectronic semiconductor components as well as a target carrier and a semiconductor device with some aspects according to the proposed principle; and

FIGS. 9A to 9H illustrate an embodiment of a method for transferring optoelectronic semiconductor components as well as a target carrier and a semiconductor device with some aspects according to the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

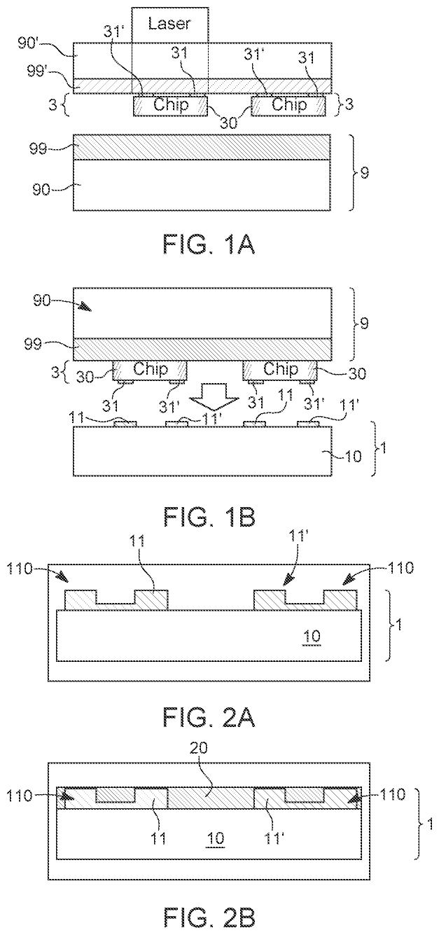

In a transfer process, the shrinkable receiving layer and the receiving surface there are important parameters for a reliable process. Based on this, conventional techniques use a process in which the components are first transferred to an intermediate carrier and then from this to the target carrier. FIGS. 1A and 1B show a schematic representation of such a conventional process.

The semiconductor components 30 are attached to a source carrier 90′ via a corresponding adhesive layer 99′. Each of the semiconductor components comprises a semiconductor body 30 and two contact pads 31 and 31′ on its surface. The contact pads 31 and 31′ are connected to the shrinkable release layer 99′. The side of the semiconductor body 30 facing away from the contact pads faces the target carrier 9. This target carrier 9 also comprises a substrate 90 as well as a structured, sticky and flat collecting layer 99 arranged thereon.

For a mass transfer, a laser light pulse is now applied to the shrinkable release layer 99′, which leads to a significant reduction in the adhesive force between the semiconductor component 3 and the adhesive layer 99′. The components fall downwards due to a transmitted pulse and gravity and adhere to the layer 99. This first process thus transfers the components to an intermediate carrier, which also acts as a source carrier 9 in the further process. The next transfer step to the actual target carrier 1 is shown in FIG. 1B. In a similar way to FIG. 1A, the semiconductor components 3 are aligned with their contact pads 30 or 31 so that their contact pads are positioned over contact areas 11 and 11′ of the target carrier. The interface between the semiconductor body 30 and the shrinkable collecting layer 99 is then changed again, for example by a laser light pulse (another laser transfer), so that its adhesive force is significantly reduced and the component falls towards the contact areas 11 and 11′.

In this conventional approach, the transfer to the target surface is generally carried out by means of a catch layer applied over the entire surface, which holds the component in position due to its stickiness. The shrinkable catch layer can then form the shrinkable catch layer in a further transfer step. Alternatively, there is also the option of using special solder pastes as a catch layer for the final transfer step to a final target carrier. However, the choice of materials is very limited here, as the pastes require special mechanical properties in order to minimize bouncing of components during the transfer process. Furthermore, the correct positioning and alignment of small components and the supply of suitable solder pastes present additional difficulties due to the limited choice of materials and small dimensions.

A process according to the proposed principle results in significantly more degrees of freedom for the various materials, in particular the solders to be used. In addition, the invention allows a certain degree of flexibility with regard to capturing and holding the semiconductor bodies, as this process and the subsequent electrical contacting can still be carried out separately from each other, but nevertheless without additional steps in a joint process.

The following figures show various embodiments for a target carrier, for a finished semiconductor device and for the method of transferring finished components to the target carrier. The term “target carrier” is understood here to mean the carrier to which the component is finally mechanically and electrically contacted. The concept according to the invention is not limited to the optoelectronic components shown in the embodiment example, but can generally be realized for any type of semiconductor components regardless of the number of their contact pads.

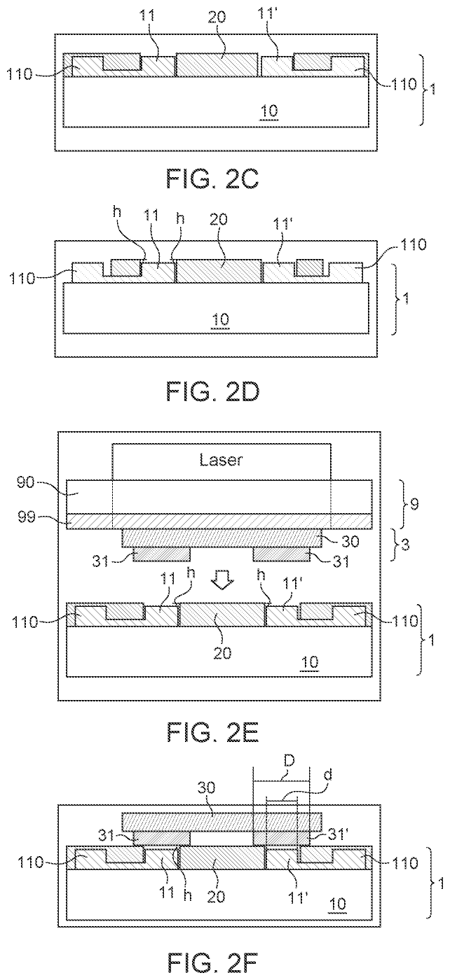

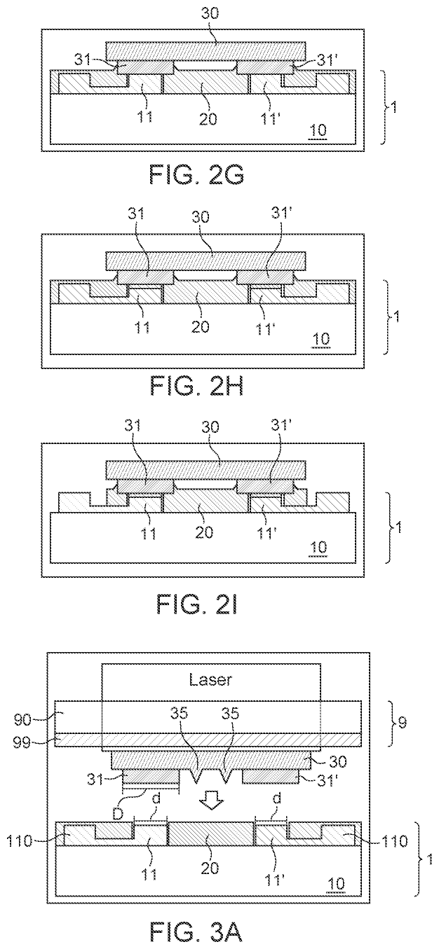

FIGS. 2A to 2I show a first example of a process for transferring such components. In FIG. 2A, the target carrier is prepared accordingly. The target carrier comprises a base substrate 10 to which a plurality of line structures 110 are applied. The base substrate 10 can be formed by a glass carrier, a ceramic carrier, but also a PCB board, an interconnect layer or another semiconductor component. In this respect, it is therefore also possible to form the carrier 10 as an integrated circuit or with one or more integrated circuits. A large number of line structures 110 are applied to the surface of the carrier 10. On the one hand, these can lead to other components on the carrier 10, to integrated circuits within the carrier 10, but can also form additional contact lugs for further external contacting. The line structures 110 each have contact areas 11 and 11′ aligned with one another, which rise above the surface of the carrier 10. The contact areas 11 and 11′ are positioned relative to each other in such a way that the distances between their respective centers correspond to the distances between the centers of contact pads for the semiconductor components to be transferred.

Carrier 10 is made of various materials, the line structures 110 are made of a conductive material, with solder also being applied to the surface of the contact areas 11. Alternatively, the contact pads of the semiconductor component to be transferred can also be covered with solder material. In a further embodiment, it is also possible for the contact areas to be formed with a solder material.

In a subsequent step, a two-dimensional shrinkable collecting layer 20 is applied to the target carrier 1, which encloses the line structures 110 including the contact areas 11 and covers them with a thin material layer of the shrinkable collecting layer as shown in the present embodiment example.

In this context, conventional materials as well as metal compounds, for example on a gold-tin or gold-indium basis, can be applied as solder material. Additional solder pastes are not required, but can also be applied to the surface of the contact areas 11 and 11′.

The collection material consists of a structurable photoresist in which an epoxy is also incorporated. Alternatively, a silicone with a high coefficient of thermal expansion or a plastic that leads to cross-linking shrinkage when exposed to heat or other parameter changes can also be used. In some aspects, the applied collecting layer is additionally provided with a solvent so that the volume of the shrinkable collecting layer is significantly increased compared to the shrinkable collecting layer without the solvent. When the solvent evaporates, the shrinkable collecting layer shrinks. The shrinkable interception layer 20 is applied to the surface by means of spin coating so that the surface is as uniform as possible and, as shown, its thickness is such that the material slightly covers the line structures 110.

In a subsequent process step, the surface is structured and partial areas of the shrinkable collecting layer 20 are removed again. In detail, these are the areas above the contact areas 11 and 11′, whereby the material of the shrinkable collecting layer 20 adjacent to the edges of the contact areas 11 and 11′ is also removed. This results in the shape shown in FIG. 2C, in which the surface of the contact areas 11 and 11′ is exposed and the material of the shrinkable collecting layer is slightly spaced from the contact areas. In other words, there is a small gap around the contact areas between the areas 11 and 11′ and the shrinkable collecting layer 20. The thickness or lateral dimension of this gap is in the range of a few nm to fractions of μm in small embodiments, and may be in the range of a few micrometers in larger embodiments.

If a photoresist layer is used for the layer 20, it can be structured directly by a suitable exposure and subsequent etching process. Alternatively, it is also possible to apply an additional photomasking to the shrinkable collecting layer 20, structure it and then remove the material of the shrinkable collecting layer 20 around the contact areas 11 in a suitable manner.

In a further or simultaneously performed structuring process, the line structures 110 are exposed on the surface of the carrier in step 2D, so that essentially 3 separate collecting layer elements are formed. The embodiments shown in FIGS. 2C and 2D form versions of target carriers on which the semiconductor components are transferred in a subsequent process step by means of a laser lift-off process. The structure shown in FIG. 2D makes it possible to electrically contact the semiconductor body subsequently placed on the contact areas via the line structures 110 by means of a bonding process or another measure. In this respect, above all the components of the material of the shrinkable collecting layer are removed, where access to the line structures 110 or to the carrier 10 is to take place later. In the case of the target carrier in FIG. 2C, such a step must be carried out after the transfer process has been completed.

The transfer process is shown in FIG. 2E. A source carrier 9 with a carrier 90 and a layer 99 on it is positioned together with a component 3 over the contact areas 11 and 11′. The component 3 comprises a semiconductor body 30 and, in the embodiment example, two contact pads 31 and 31′. The distances between the centers of the two contact pads 31, 31′ correspond to the distances between the two centers of the contact areas 11 and 11′. However, as already shown in FIG. 2, the surface area or the lateral distance of each contact pad 31, 31′ is greater than the corresponding surface area on the contact areas 11 and 11′.

In this way, the surface of the contact areas 11 and 11′ is slightly set back from the surface of the shrinkable collecting layer 20. The difference amounts to fractions of a micrometer, but creates a small gap when a semiconductor body is subsequently placed on the shrinkable collecting layer, which is compensated for again by a subsequent shrinking process of the shrinkable collecting layer 20, which is still shown.

A laser beam that is now irradiated vaporizes part of the layer 99 so that the component 3 falls towards the shrinkable collecting layer and the contact areas 11, 11′. Upon reaching the shrinkable collecting layer 20, the contact pads 31 and 31′ are held in place by slightly adhering to the shrinkable collecting layer 20. Since the lateral dimension of the contact pads 31 and 31′ is larger than the corresponding dimension of the contact areas 11 and 11′, the contact pads 31 and 31′ overlap and lie on an edge of the shrinkable interception layer 20 surrounding the contact areas. The small air gap defined by the height h is present between the surface of the contact pads and the surface of the contact areas.

In a subsequent step, shown in FIG. 2G, the assembly produced in this way is subjected to a heating process. This also heats the shrinkable collecting layer 20, which begins to shrink under the effect of heat. At the same time, a material of the shrinkable collecting layer on the side walls of the contact pads is pulled slightly upwards by a capillary effect, so that material now extends on the underside of the contact pads as well as along the side walls of the contact pads in the direction of the semiconductor body 30. The shrinking process exerts a tensile force on the semiconductor component 3 and pulls the contact pads 31, 31′ onto the contact areas 11 and 11′. This tensile force should be sufficiently large to enable an at least now already electrically conductive contact between the areas 11, 11′ and the contact pads 31 and 31′; on the other hand, however, it should not be too large that the material of the shrinkable collecting layer tears off the contact pads again during the shrinking process.

In a further subsequent heating process, the temperature is increased to such an extent that the solder material present on the contact pads or the contact areas melts and forms a metallic connection on the surface of the contact areas with the corresponding surface of the contact pads. As a result, the component is not only electrically but also mechanically attached to the contact areas 11 and 11′. The shrinking process of the shrinkable catch layer is already completed during the process, but can also continue so that a sufficient tensile force is exerted on the component in the direction of the contact areas 11 and 11′ even during the melting of the solder material. Alternatively, as also shown in further embodiments, an additional pressure element can be provided, which presses the semiconductor component lightly against the contact areas 11. FIGS. 2G and 2H show the solder melting process and the result.

In a final step in FIG. 2I, part of the material of the shrinkable collecting layer is now removed so that it only remains in the edge area of the contact pads. The material of the shrinkable collecting layer forms a natural protection against possible corrosion or other contamination effects, so that in addition to providing support during the transfer process, the service life of the component can also be increased. Alternatively, the collecting material can also be removed completely so that the component is only held mechanically by the solder material melted onto the contact areas 11 and 11′.

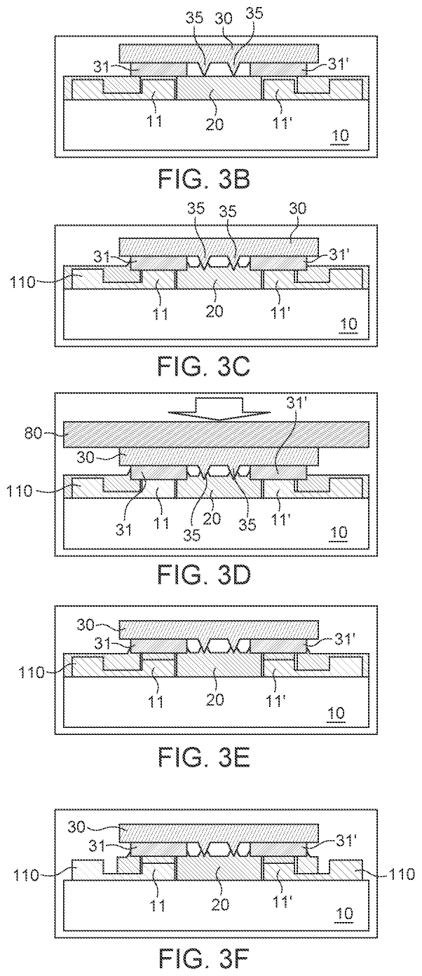

FIGS. 3A to 3F show a further embodiment of a method for transferring components according to the proposed principle. Devices with the same function are marked with the same reference symbols. Partial FIG. 3A shows the transfer process, whereby the target carrier 1 has already been fully processed as in the previous example. In addition to the carrier 10 and the contact areas 11 and 11′, it also comprises the collecting layer 20 protruding above the contact areas, whereby the shrinkable collecting layer 20 is removed above the contact areas 11 and 11′ and slightly spaced apart from them.

The semiconductor device is also designed here as an optoelectronic component in the form of a horizontal μ-LED. In addition, however, the semiconductor body 30 between the two contact pads 31, 31′ also comprises two locking elements 35 in the form of pyramid-shaped tips, the dimensions of which correspond at least to the thickness of the contact pads 31 and 31′. These locking elements in the form of tips 35 can alternatively also protrude beyond the contact pads. In a laser lift-off process as shown in FIG. 3A, the component is accelerated towards the target carrier 1 and, as shown in FIG. 3B, strikes its surface and in particular the edge areas of the shrinkable catch layer 20.

At the same time, the locking elements 35 touch the surface of the shrinkable interception layer or also penetrate it slightly. During a subsequent thermal shrinking process in FIG. 3C, the material of the shrinkable catch layer is drawn towards the semiconductor body 3 due to various capillary effects, both at the edge area of the contact pads 31 and 31′ and along the pyramid-shaped locking elements 35. The additional locking elements 35 prevent the component from slipping in a lateral direction during the shrinking process. The pyramid-shaped tips on the semiconductor body in FIGS. 3A to 3C improve not only the capture properties but also the tensile force during the shrinking process of the capture material. This is generated by increased capillary forces of the material at the pyramid-shaped steps, which move upwards during the shrinking process and thus pull the semiconductor component more strongly onto the contact surfaces of the target carrier.

As shown in FIG. 3D, the shrinking process can also be supported by an externally arranged element in the form of a pressure plate 80. The pressure plate 80 is applied to the side of the semiconductor body 30 facing away from the contact pads and presses the component downwards during the shrinking process and the subsequent melting process for the solder. This also results in the larger material at the edge of the contact pads and the tip of the locking elements in FIG. 3E.

In a further subsequent process in step 3E, the solder material applied to the contact surfaces or contact pads is heated and thus forms a mechanically stable and electrically conductive connection.

In a final subsequent process step in FIG. 3F, as in the previous example, material of the shrinkable collecting layer 20 is removed in areas of the line structure 110 so that these are accessible for further process control. The material of the shrinkable collecting layer 20 remains only in the edge area of the contact pads 11, 11′ and below the contact pads 31 and 31′.

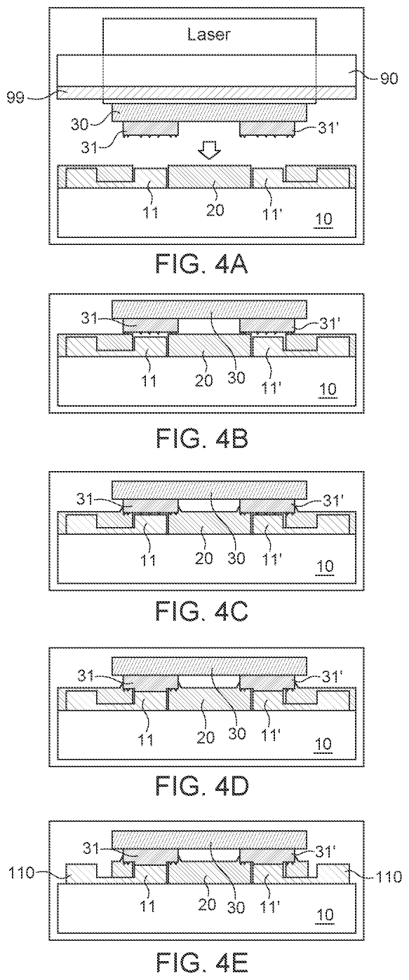

FIGS. 4A to 4E show a method in which an additional structure is applied to the contact pads 31 and 31′ of the semiconductor component 3. In the present embodiment example, the additional structures are designed as small elevations which, when the semiconductor body is deposited by the irradiated laser beam, see FIG. 4A, engage in the uppermost layer of the shrinkable collecting layer 20 around the contact areas 11 and 11′. The structuring is in the range of a few nanometers and at most a few micrometers. As shown in FIG. 4B, the structures on the contact pads are designed in such a way that they do not initially touch the contact areas 11 and 11′ when the semiconductor body is placed on the shrinkable collecting layer. On the other hand, the protrusions engage slightly in the edge of the shrinkable collecting layer 20.

As a result of the heating and shrinking process of the shrinkable collecting layer 20 shown in FIG. 4C, this generates a tensile force which pulls the semiconductor component and the two contact pads 31 and 31′ onto the contact areas 11 and 11′, so that the surface structures can now engage in the contact areas. It is conceivable to provide a very soft material on the contact areas, for example in the form of a solder paste, so that the surface structures easily press into the solder paste during the shrinking process and thus create a good electrical connection without any further measures. In a subsequent step, shown in FIG. 4D, the paste is now heated, melts and thus connects the contact pads 31 and 31′ of the semiconductor body with the contact areas 11 and 11′. In this embodiment example, the material of the shrinkable collecting layer 20 is also removed again in the area of the other line structures and in particular outside the semiconductor body, resulting in the figure shown in FIG. 4E.

In the process shown in FIGS. 4A to 4E, the additional structures for improved retention are applied to the shrinkable catch layer on the contact pads 31 and 31′ of the semiconductor body. However, the contact areas 11 and 11′ can also be formed in the same way and provided with an additional locking or roughening. The topography shown improves the catching behavior of the component in the contact area. The topography on the contact pads and/or the contact areas generates a high punctual contact force when the catching material of layer 20 shrinks, which then leads to a more reliable connection during the soldering process. If necessary, the structures in the area of the contact pad can also lead to an increased capillary force, which increases the tensile force during the shrinking process and thus strengthens the mechanical contact between the contact pad and the contact area.

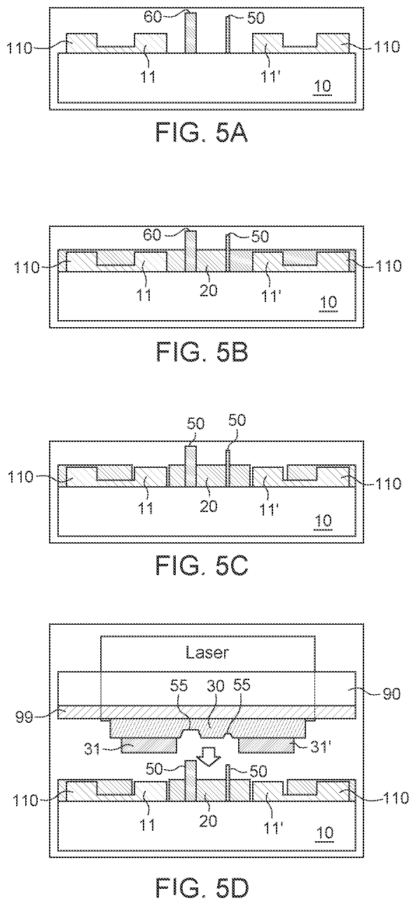

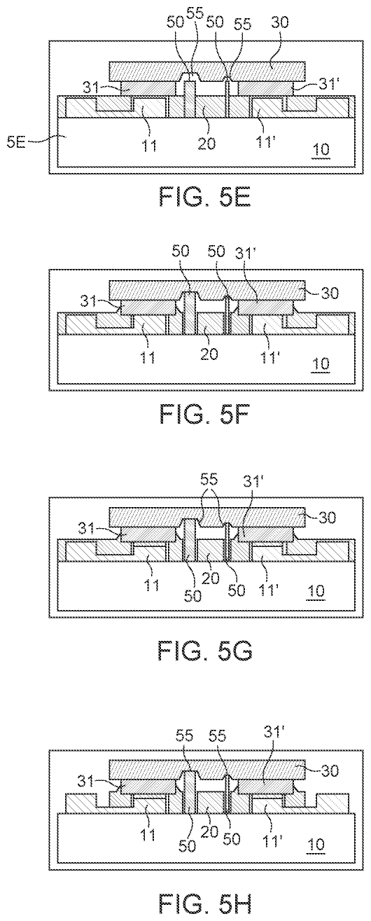

In a further aspect, such a topography can also be used for improved alignment during the transfer process. In addition to the topographies for the contact pads and the contact areas, other structures on the semiconductor body or the target carrier can also be used for this purpose. The embodiments in parts FIGS. 5A to 5H show such an embodiment example.

In FIG. 5A, a target carrier is provided which, in addition to the line structures 110 and the contact areas 11 and 11′ connected thereto, also has alignment elements 50. In the present embodiment example, the alignment elements protrude beyond the contact areas 11 and 11′ and are also designed differently. The different designs of the locking and alignment elements 50 make it possible to place semiconductor components on the contact areas 11 and 11′ so that they cannot twist. The height of the locking and alignment elements 50 is selected in such a way that, in a finished state, they engage with corresponding mating structures on the semiconductor component and align it in a suitable manner.

In a subsequent processing step in FIG. 5B, the material of the shrinkable catch layer 20 is spun, sputtered or otherwise applied so that it slightly covers the line structures 110 and the contact pads 11 and 11′. This process step corresponds to the manufacturing process in the previous embodiments, with the locking and alignment elements 50 protruding beyond the material of the shrinkable collecting layer. With an etching process carried out in FIG. 5C, the surfaces of the contact areas 11 and 11′ are exposed and freed from any remaining material of the shrinkable collecting layer 20. The etching process also ensures that the material of the shrinkable interception layer is slightly spaced from the individual contact areas 11 and 11′. The locking and alignment elements 50 are also processed in the same way, so that the material of the shrinkable catch layer is also slightly spaced from the edge of the locking and alignment elements. This has the advantage that during the shrinking process, the locking and alignment elements do not feel any lateral tension or pressure and thus cannot warp or shift during the shrinking process.

The transfer process is shown in sub-FIG. 5D. For this purpose, the semiconductor body 30 of the semiconductor component 3 comprises a locking and alignment element 55 corresponding to the locking and alignment elements 50 on the target carrier. In the present embodiment example, these are designed as recesses of different sizes so that the alignment elements 50 on the target carrier can engage precisely in them. In this way, on the one hand, incorrect positioning of the semiconductor component is prevented and, on the other hand, the opening in the semiconductor body 30 shown in FIG. 5D allows self-alignment to take place at least in a small area.

After the semiconductor component has been placed on the material of the shrinkable collecting layer in FIG. 5E, the locking and aligning elements 50 and 55 are still a little way apart. In particular, they do not lie directly against the respective surfaces, since otherwise the shrinking process that takes place later cannot take place completely or with the necessary tensile force. Specifically, the distance between the base surface of the structures 55 on the semiconductor body 30 and the upper surface of the locking and alignment elements 50 on the target carrier is selected such that it at least corresponds to the distance between the contact pads and the contact areas. Put simply, the distances between the locking and alignment elements are approximately identical to the gap between the contact areas and the contact surfaces.

Due to the subsequent shrinking process and the resulting change in volume of the material of the shrinkable collecting layer, the locking and alignment elements 50 and 55 are brought together and the component is simultaneously centered and, if necessary, fine-adjusted. This is possible because the shrinkable collecting layer is much more flexible than the locking and alignment elements. The elements 50 and 55 can also be used to compensate for a slight tilt, i.e. tilting of the component.

In subsequent process steps shown in FIGS. 5G and 5H, the solder material on the contact area 11 du 11′ or contact pads 31 and 31′ is heated so that the contact pads are mechanically, thermally and electrically connected to the contact areas. The locking and alignment elements 50 and 55 remain essentially unchanged. In a final step in FIG. 5H, excess material of the shrinkable catch layer 20 is removed again.

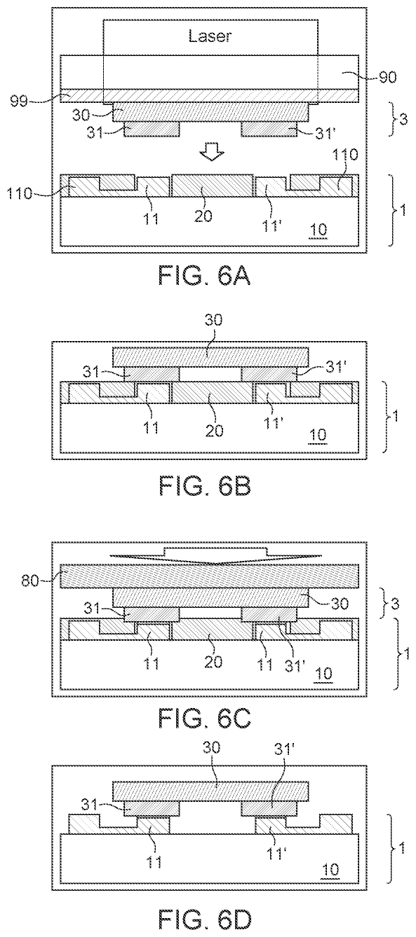

The method shown here uses a catch layer 20, which in some embodiments consists of a photoresist layer with additional materials such as epoxy. Alternatively, however, it is also possible to use a different material, in particular a plastic material, which in itself only has a lower adhesive strength, but is particularly soft or viscous and has thermoplastic properties. The embodiments in FIGS. 6A to 6D show such an embodiment in which the catching material consists of a soft polymer. As in the previous examples, target carrier 1 is produced by depositing the polymer over a large area on the conductive and contact areas by spin coating, sputtering or a similar process and then structuring it. In a laser lift-off process of FIG. 6A, the semiconductor component 3 with its semiconductor body 30 is detached from the upper adhesive layer 99 of the source carrier 90 and deposited with its contact pads, 30 and 31′ on the contact areas 11 and 11′. As shown in the previous examples—in FIG. 6B—there is a small gap between the surface of the contact pads and the surface of the contact areas.

In a subsequent step, shown in FIG. 6C, a further pressure element 80 is now applied and the semiconductor component 3 is pressed downwards at an increased temperature. The polymer material of the shrinkable collecting layer 20, which becomes softer with increasing temperature, deforms until the contact pads 31 lie directly on the contact areas 11 of the target carrier. A further heating process causes the solder material applied to the contact areas 11, 11′ to bond with the contact pads 31, 31′, creating a corresponding connection.

This is shown in FIG. 6C. The deformation of the soft polymer material of the shrinkable catch layer occurs due to the mechanical pressure process of melting the solder material. In this respect, the polymer can be easily compressed at an elevated temperature while the solder of the contact areas on the target surface is melted. However, there is no or only a very small capillary effect, so that the material does not shrink in contrast to the previous versions, i.e. the material of the shrinkable collecting layer does not creep up along the side walls of the contact pads. Once the soldering process is complete, the shrinkable collecting layer 20 can be completely removed from around the line structures and contact areas, resulting in the structure shown in FIG. 6D. This is also conceivable in the other embodiments if the material of the shrinkable collecting layer is completely removed.

The process presented is suitable, among other things, for transferring semiconductor components with very small lateral dimensions in a simple manner. The size of the components is not limited downwards, but can be in the range of less than 10 μm or even less. On the other hand, it is also possible to transfer larger semiconductor components with an edge length of several 100 μm or even millimeters. The advantage of transferring large components in this way is that the shrinkable collecting layer can be applied by direct stencil printing, for example, rather than by spin coating and subsequent structuring. This avoids an additional lithography step.

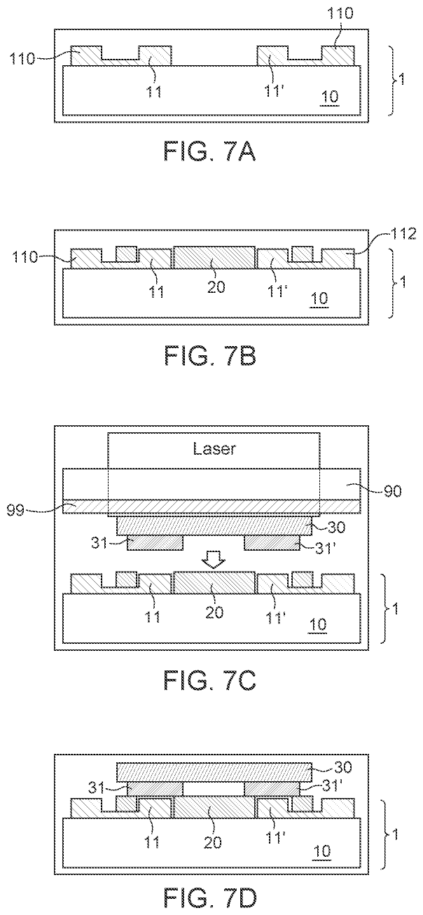

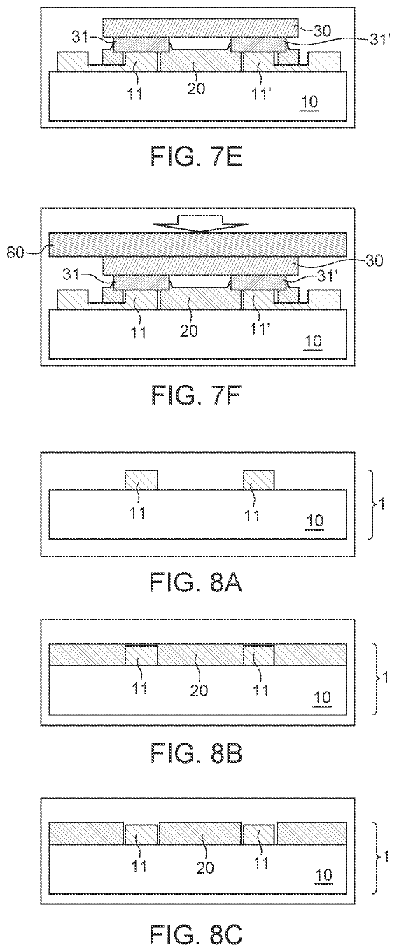

The embodiment of FIGS. 7A to 7F shows an example of such a method. Here again, a target carrier 1 is provided which, in addition to a carrier, also comprises a plurality of line structures 110 located on this carrier with associated contact areas 11 and 11′. In contrast to the previous examples, however, the shrinkable collecting layer 20 is now applied directly by means of stencil printing, with the material of the shrinkable collecting layer slightly protruding above the surface of the contact areas 11 and 11′ on the one hand and being spaced apart from them on the other. Here too, the area of the contact areas enclosed by the material of the shrinkable collecting layer 20 is selected so that it is smaller than the corresponding area of the contact pads 31 and 31′.

In a subsequent transfer process, the semiconductor component is positioned accordingly and detached from the source carrier 90 and 99 by means of a laser lift-off process in FIG. 7C and placed on the shrinkable collecting layer 20, see FIG. 7D. In a subsequent shrinking process in FIG. 7E, which in this embodiment example is carried out by a chemical cross-linking process of the applied material of the shrinkable collecting layer, the semiconductor body is pulled downwards with its contact pads in the direction of the contact areas. This process and the subsequent soldering process in FIG. 7F are supported by a pressure element 80. Due to the stencil pressure, subsequent removal of catching material on the lead areas 110 may not be necessary.

In addition to the optoelectronic devices or semiconductor devices with multiple contacts on one side shown here, the proposed method can also be used to attach vertical components, i.e. components with contact pads on different sides, to the target carrier 1.

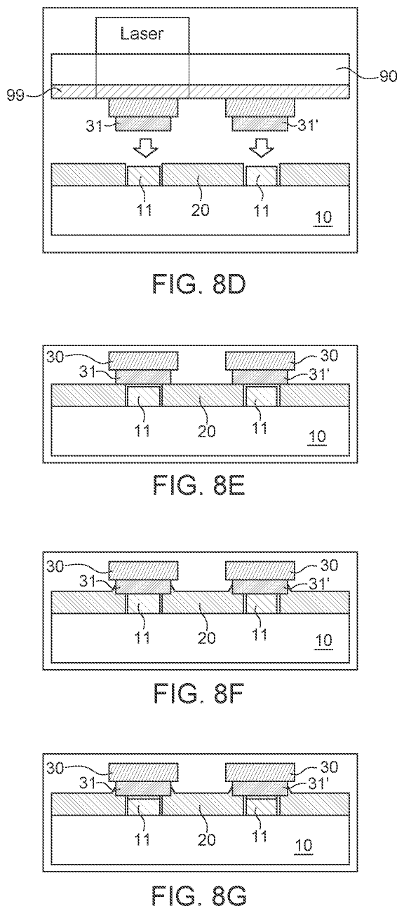

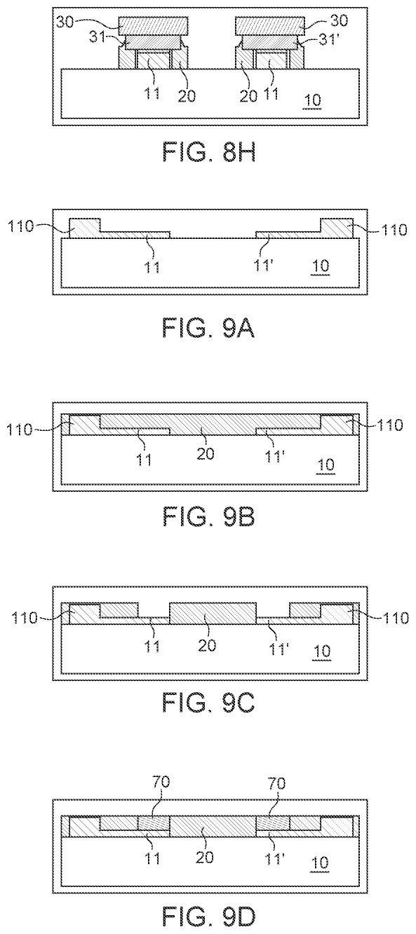

FIGS. 8A to 8H show an example of such a process. In FIGS. 8A to 8C, the target carrier is produced by applying individual contact areas 11 to a carrier 10. The material of the shrinkable catch layer 20 is then applied by sputtering or spin coating and completely covers the contact areas 11. In addition to a sticky component, the material of the shrinkable catch layer also comprises a vaporizable component, which ensures the shrinking process in a subsequent step. After structuring in FIG. 8C, the target carrier is ready for mass transfer. As also shown in the previous embodiments, the thickness of the shrinkable collecting layer 20 is slightly greater than the thickness of the corresponding contact areas 11, so that the surface of the shrinkable collecting layer 20 protrudes slightly beyond the surface of the contact areas 11 and 11′.

FIG. 8D shows the transfer process in which a large number of semiconductor components with their contact pads 31 fall onto the contact areas 11 via a laser lift-off process and come to rest at a slight distance along an edge area of the shrinkable collecting layer 20 around the contact areas 11. Subsequently, in FIG. 8F, the solvent evaporates, so that here too the sticky component of the shrinkable collecting layer 20 extends along the edge of the contact pads in the direction of the semiconductor body due to the capillary forces.

The tensile force triggered by the shrinking process due to the evaporation of the solvent pulls the individual semiconductor bodies towards the contact areas, as shown in FIG. 8F. In a subsequent step in FIG. 8G, the soldering process is carried out so that the contact areas 11 are mechanically, thermally and electrically connected to the contact pads 31. The shrinkable catch layer can then be removed. As in the previous examples, this is done either completely or in such a way that a small part of the shrinkable collecting layer 20 remains around the individual contact areas 11. This allows the contact areas 11 and the connection between the contact pads 31 and 11 to be at least partially protected from corrosion or other damage by the material of the shrinkable collecting layer.

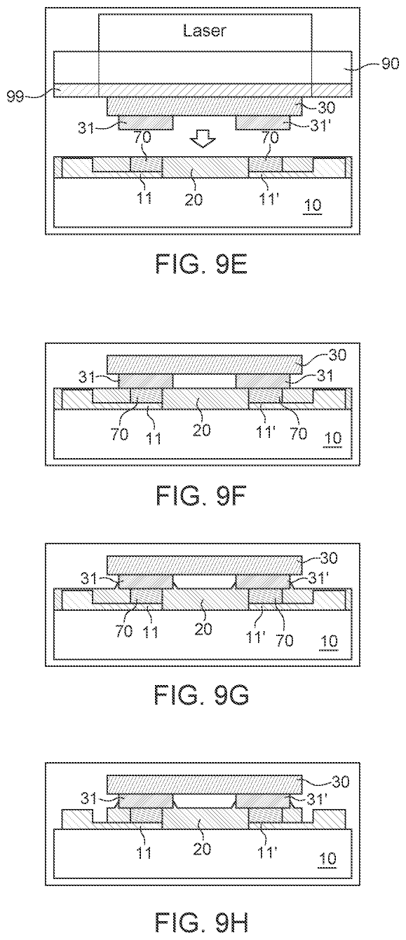

A further embodiment is shown in sub-FIGS. 9A to 9G In this embodiment example, the focus is on the fact that a continuous and uniform height can be set by additionally applying a solder paste after the contact areas 11, 11′ have been exposed. In FIG. 9A, a large number of line structures 110 are applied to the surface of the carrier and the contact areas 11, 11′ are prepared. These contact areas 11 are provided as simple contacts, i.e. without an additional elevation or other measure. The material of the shrinkable collecting layer 20 in FIG. 9B is then applied over a large area and subsequently structured in FIG. 9C so that the contact areas 11 and 11′ are exposed on the line structures 110. In this embodiment example, however, the difference between the surface of the shrinkable collecting layer 20 and the surface of the contact areas 11 is significantly larger than in the previous embodiment examples. The resulting gap is now filled with a solder paste 70 by squeegeeing and the excess solder material is then removed again. The solder paste itself can also have slightly sticky properties. This results in a uniform and even surface as shown in FIG. 9D.

A laser lift-off process of FIG. 9E is then carried out and the components are placed with their contact pads 30 and 31 directly on the shrinkable collecting layer 20 and over the contact areas 11 and 11′ as well as the solder paste 70. Here too, the surface of the contact pads 31 is larger than the corresponding surface of the solder paste 70, so that the contact pads protrude at least partially beyond the solder paste 70 onto the surface of the shrinkable collecting layer 20, as shown in FIG. 9F.

A shrinking process is then carried out in FIG. 9G so that the semiconductor components are pulled slightly downwards by the shrinking collecting layer. Here too, capillary forces cause the material of the shrinkable collecting layer to flow along the edge in the direction of the semiconductor body 30. The viscous solder paste 70 can also show a change in volume on the one hand, but on the other hand it can also enter any remaining cavities or gaps. It is also possible to melt the solder paste by a further heating process and thus create a mechanical and conductive connection between the contact areas 11 and the contact pads 31. In a final step, excess material from the shrinkable catch layer is removed again.

1.-18. (canceled)

19. A target carrier for transferring semiconductor components, wherein the semiconductor components comprise at least one contact pad and a structuring, the target carrier comprising:
a target substrate with at least two contact areas; and
a shrinkable collecting layer arranged around each of the at least two contact areas and projecting beyond the at least two contact areas, wherein a lateral distance between two opposite edges of the shrinkable collecting layer around each of the at least two contact areas is smaller than a lateral dimension of the at least one contact pad, wherein the shrinkable collecting layer around the at least two contact areas is designed such that its structuring is configured to penetrate into the shrinkable collecting layer with a substantially central alignment of the at least one contact pad relative to one of the at least two contact areas.

20. The target carrier according to claim 19,
wherein an area recessed from a material of the shrinkable collecting layer around each of the at least two contact areas is smaller than an area of the at least one contact pad, and/or
wherein the shrinkable collecting layer is arranged at a distance around each of the at least two contact areas, the distance optionally being less than 25% of a lateral dimension of the at least one contact pad or of one of the at least two contact areas, and/or
wherein the shrinkable collecting layer comprises at least one of the following materials:
a photoresist material,
an epoxy, or
a silicone with a high coefficient of thermal expansion.

21. The target carrier according to claim 19,
wherein a solder material is located at the at least two contact areas, and/or
wherein a distance between centers of the at least two contact areas substantially coincides with a distance between centers of two contact pads of the semiconductor components.

22. The target carrier according to claim 19, further comprising a first alignment element projecting beyond the shrinkable collecting layer and corresponding to a second alignment element of a semiconductor component such that, when the first alignment element is aligned with the second alignment element of the semiconductor component, the at least one contact pad is aligned with one of the at least two contact areas.

23. The target carrier according to claim 19, wherein the shrinkable collecting layer is configured to:
shrink when exposed to heat,
shrink by applying a force that is essentially perpendicular to the contact areas,
shrink by vaporizing a liquid component dissolved in the shrinkable collecting layer, or
shrink by a chemical process.

24. The target carrier according to claim 19, wherein a difference between a height of the at least two contact areas and a surface of the shrinkable collecting layer is less than 40% of a thickness of the shrinkable collecting layer, and wherein the thickness is in a range from 300 nm to 2.5 μm.

25. A semiconductor arrangement comprising:
the target carrier according to claim 19; and
a semiconductor component comprising a semiconductor body and at least one contact pad and a structuring, which is mechanically and electrically fastened with the at least one contact pad to one of the at least two contact areas, wherein the contact pad protrudes beyond a surface of the contact area and a protruding part is at least partially connected to the shrinkable collecting layer, and wherein the structuring engages in the shrinkable collecting layer.

26. The semiconductor arrangement according to claim 25, wherein a material of the shrinkable collecting layer extends at least partially along an edge of the contact pad of the shrinkable collecting layer towards the semiconductor body.

27. The semiconductor arrangement according to claim 25, wherein the structuring is formed on the at least one contact pad, and/or wherein the structuring comprises a locking element, which projects beyond the contact pad and engages in the shrinkable collecting layer.

28. The semiconductor arrangement according to claim 25, wherein the semiconductor body comprises an alignment member corresponding to the alignment member of the target carrier, optionally a part of a material of the shrinkable collecting layer extending over the surface of the shrinkable collecting layer towards the semiconductor body.

29. The semiconductor arrangement according to claim 25, further comprising a solder material located between the contact pad and the one of the at least two contact areas, wherein a thickness of the solder material is substantially equal to or smaller than a distance of the surface of the contact area from the surface of the shrinkable collecting layer.

30. A method for transferring semiconductor components, the method comprising:
providing at least one semiconductor component with at least one contact pad and a structuring;
providing a target carrier having at least two contact areas and a shrinkable collecting layer disposed around each of the at least two contact areas and overlapping the at least two contact areas, wherein a lateral distance between a material of the shrinkable collecting layer around each of the at least two contact areas is smaller than a lateral dimension of the at least one contact pad,
positioning the at least one semiconductor component over the target carrier such that the at least one contact pad is located opposite the contact area with the structuring engaging in the shrinkable collecting layer;
placing the at least one contact pad on an edge of the shrinkable collecting layer over one of the at least two contact areas;
performing a shrinking process so that the at least one contact pad is pulled against the one of the at least two contact areas; and
mechanical and electrical fastening the contact pad to one of the at least two contact areas.

31. The method according to claim 30, wherein providing the target carrier comprises:
providing a carrier;
forming line structures on a surface of the carrier, wherein the line structures comprise the at least two contact areas; and
forming a structured shrinkable collecting layer on the carrier.

32. The method according to claim 31, wherein forming the structured shrinkable collecting layer comprises:
forming a flat shrinkable collecting layer on the surface of the carrier covering the line structures and the contact areas; and
structuring the flat shrinkable collecting layer and removing material from the shrinkable collecting layer so that the contact areas and an area around the contact areas are exposed.

33. The method according to claim 30, further comprising:
applying a solder material to the at least two contact areas prior to a formation of the structured shrinkable collecting layer, or
squeegeeing solder material into openings in the shrinkable collecting layer where the contact areas are exposed and remove excess solder material from a surface of the shrinkable collecting layer to form a substantially uniform surface.

34. The method according to claim 30, wherein the target carrier comprises at least one alignment element aligned with at least one corresponding alignment element of the at least one semiconductor component during a positioning of the at least one semiconductor component so that they interlock during a shrinking process.

35. The method according to claim 30,
wherein the structuring is arranged on the at least one contact pad at least in its edge region, and/or
wherein the structuring comprises at least one locking element which projects beyond the contact pad and engages in the shrinkable collecting layer.

36. The method according to claim 30, wherein performing the shrinking process is carried out by:
heating the shrinkable collecting layer above a threshold temperature; and/or
exerting a force substantially perpendicular to the contact areas on the shrinkable collecting layer; and/or
vaporizing a liquid component dissolved in the shrinkable collecting layer; and/or
chemical cross-linking of components in the shrinkable collecting layer.
